(19) United States
(12) Patent Application Publication
(10) Pub. No.: US 2026/0167902 A1
(43) Pub. Date: Jun. 18, 2026

(54) SEMICONDUCTOR SUBSTRATE PROCESSING LIQUID

(71) Applicant: Kao Corporation, Tokyo (JP)

(72) Inventor: Kouhei YAMADA, Wakayama (JP)

(73) Assignee: Kao Corporation, Tokyo (JP)

(21) Appl. No.: 19/126,858

(22) PCT Filed: Nov. 1, 2023
(86) PCT No.: PCT/JP2023/039502

§ 371 Date: May 2, 2025

(30) Foreign Application Priority Data
Nov. 4, 2022 (JP) 2022-177316

(51) Int. Cl. C11D 7/50; C11D 7/26; C11D 7/34; H10P 70/00

(52) U.S. Cl. CPC C11D 7/5022; C11D 7/261; C11D 7/34; H10P 70/23; C11D 2111/22

(57) ABSTRACT

Provided is a treatment solution for a semiconductor substrate that has ahigh ability to remove organic matter on a substrate.

An aspect of the present disclosure relates to a treatment solution for a semiconductor substrate. The treatment solution contains an aromatic solvent (component A) and an organic acid (component B). The component A contains aromatic ether.

### TECHNICAL FIELD

The present disclosure relates to a treatment solution for a semiconductor substrate and a cleaning method using the treatment solution.

### BACKGROUND ART

A manufacturing process of a semiconductor device includes various steps such as lithography and etching. Usually, a step of treating unnecessary organic matter and inorganic matter present on a substrate with a treatment solution is performed after finishing each step or before moving to the next step.

For example, JP 2017-168804A (Patent Document 1)proposes a liquid chemical as a treatment solution for cleaning a substrate that has a circuit pattern. The liquid chemical contains a specific alkoxysilane, specific sulfonic acids, and at least one solvent selected from hydrocarbon, ether, and thiol.

### Disclosure of the Invention

An aspect of the present disclosure relates to a treatment solution for a semiconductor substrate. The treatment solution contains an aromatic solvent (component A) and an organic acid (component B). The component A contains aromatic ether.

An aspect of the present disclosure relates to a cleaning method that includes cleaning a substrate having organic matter by using the treatment solution of the present disclosure.

An aspect of the present disclosure relates to a removal method that includes removing organic matter present on a substrate from the substrate by using the treatment solution of the present disclosure.

### DESCRIPTION OF THE INVENTION

A treatment solution used to remove organic matter (e.g., a resin mask and an antireflection film) and inorganic matter (e.g., particles) present on a substrate may contain a halogenated aromatic compound in order to improve its removal performance. However, the halogenated aromatic compound can generate toxic substances when incinerated.

In this regard, the treatment solution is required to have ahigh ability to remove organic matter and inorganic matter present on a substrate even if it does not contain the halogenated aromatic compound.

With the foregoing in mind, the present disclosure provides a treatment solution that has ahigh ability to remove organic matter on a substrate, and a cleaning method and a removal method that use the treatment solution.

The present disclosure can provide a treatment solution for a semiconductor substrate that has ahigh ability to remove organic matter on a substrate, and a cleaning method and a removal method that use the treatment solution.

The present disclosure is based on the findings that the use of a treatment solution containing an aromatic solvent (component A), which contains aromatic ether, and an organic solvent (component B) enables organic matter to be efficiently removed from a substrate surface.

### [Treatment Solution for Semiconductor Substrate]

In one aspect, the present disclosure relates to a treatment solution for a semiconductor substrate (also referred to as a “treatment solution of the present disclosure” in the following). The treatment solution of the present disclosure contains an aromatic solvent (component A) and an organic acid (component B). The component A contains aromatic ether.

The present disclosure provides a treatment solution for a semiconductor substrate that has ahigh ability to remove organic matter on a substrate. The treatment solution of the present disclosure is used to dean electronic components, e.g., an electronic circuit board having a resin mask, and thus makes it possible to obtain high-quality electronic components with a high yield.

The details of the mechanism of the effects of the present disclosure are not fully clear, but can be assumed as follows.

The organic acid (component B) is considered to penetrate into organic matter on a substrate, react with an acid-sensitive site present in the organic matter, and modify the organic matter. The aromatic solvent (component A) containing aromatic ether is considered to enhance the affinity of the treatment solution for the organic matter and accelerate the penetration of the organic acid (component B). Moreover, the aromatic solvent (component A) containing aromatic ether is highly soluble with the modified organic matter and may be extremely effective in removing the organic matter.

However, the present disclosure should not be interpreted solely by the above mechanism.

In one or more embodiments of the present disclosure, the organic matter on a substrate includes an organic film such as a resin mask or an antireflection film, and an organic residue such as an etching residue.

The treatment solution of the present disclosure is a treatment solution for a semiconductor substrate. In the present disclosure, the semiconductor substrate means a substrate used in the manufacturing process of a semiconductor device.

In one or more embodiments, the treatment solution of the present disclosure is used for treating organic matter in the manufacturing process of a semiconductor device.

In one or more embodiments, the treatment solution of the present disclosure may be used for removing organic matter from a substrate having organic matter. For example, the treatment solution of the present disclosure may be used as a treatment solution (e.g., a liquid remover, a stripping solution, or a cleaning solution) for removing organic matter present on a substrate, including, e.g., a resin mask, an antireflection film, and an etching residue.

In one or more embodiments, the treatment solution of the present disclosure may be used as a cleaning solution for removing particles (e.g., polishing dust or foreign matter derived from abrasive grains) remaining on or adhering to the substrate surface after polishing.

In one or more embodiments, the treatment solution of the present disclosure may be used for treating the substrate surface in the manufacturing process of a semiconductor device. For example, the treatment solution of the present disclosure may be used as a surface modifier for modifying the substrate surface.

(Component A: aromatic solvent)

The aromatic solvent (also referred to as a “component A” in the following) contained in the treatment solution of the present disclosure contains aromatic ether (also referred to as a “component A1” in the following). The component A1 may be one type or a combination of two or more types.

In one or more embodiments, the component Ais aromatic ether (component A1). In another one or more embodiments, the component A may further contain at least one selected from the group consisting of an aromatic hydrocarbon (component A2) and an aromatic alcohol (component A3) in addition to the component A1, or may not contain the component A2 or the component A3. The content of the aromatic ether (component A1) in the component Ais preferably 10% by mass or more, more preferably 20% by mass or more, and further preferably 25% by mass or more. When the component A1 is a combination of two or more types, the content of the component A1 is the total content of the two or more types.

The component A may be one type or a combination of two or more types.

### <Component A1: Aromatic Ether>

The aromatic ether (also referred to as a “component A1” in the following) is a compound having an aromatic ring and an ether bond. From the viewpoint of organic matter removal performance and safety such as flammability, the component A1 may be, e.g., a compound having an ether bond between a phenyl group that may be substituted with an alkyl group having 1 to 6 carbon atoms and an alkyl group having 1 to 12 carbon atoms, or a compound having an ether bond between phenyl groups, each of which may be substituted with an alkyl group having 1 to 12 carbon atoms. The aromatic ring may be, e.g., a benzene ring or a naphthalene ring.

The carbon number of the component A1 is preferably 7 or more and more preferably 10 or more, and is also preferably 20 or less and more preferably 14 or less from the viewpoint of organic matter removal performance and safety such as flammability.

Examples of the component A1 include veratrole (1,2-dimethoxybenzene) and diphenyl ether.

The component A preferably contains diphenyl ether from the viewpoint of improving organic matter removal performance.

### <Component A2: Aromatic Hydrocarbon>

The aromatic hydrocarbon (also referred to as a “component A2” in the following) is a compound having an aromatic ring and a hydrocarbon group. The component A2 is preferably an aromatic ring having 1 to 3 hydrocarbon groups from the viewpoint of organic matter removal performance and safety such as flammability. The hydrocarbon group is preferably an alkyl group having 1 to 3 carbon atoms and may be, e.g., a methyl group from the viewpoint of organic matter removal performance and safety such as flammability. The aromatic ring may be, e.g., a benzene ring or a naphthalene ring.

The carbon number of the component A2 is preferably 7 or more and more preferably 8 or more, and is also preferably 14 or less and more preferably 10 or less from the viewpoint of organic matter removal performance and safety such as flammability.

Examples of the component A2 include mesitylene (1,3,5 trimethylbenzene).

### <Component A3: Aromatic Alcohol>

The aromatic alcohol (also referred to as a “component A3” in the following) is a compound having an aromatic ring and a hydroxyl group. From the viewpoint of organic matter removal performance and safety such as flammability, the component A3 may be, e.g., a compound in which a hydroxyl group is bonded to at least one substituent of an aromatic ring having substituents. The substituent may be, e.g., an alkyl group having 1 to 3 carbon atoms. The aromatic ring may be, e.g., a benzene ring or a naphthalene ring. The component A3 does not include a phenol compound (in which a hydroxyl group is directly bound to an aromatic ring).

The carbon number of the component A3 is preferably 7 or more and 9 or less from the viewpoint of organic matter removal performance and safety such as flammability.

Examples of the component A3 include a benzyl alcohol.

The content of the aromatic ether (component A1) in the treatment solution of the present disclosure is preferably 10% by mass or more, more preferably 15% by mass or more, and further preferably 20% by mass or more from the viewpoint of organic matter removal performance and safety such as flammability. Furthermore, the content of the aromatic ether (component A1) is preferably 80% by mass or less, more preferably 60% by mass or less, and further preferably 30% by mass or less from the viewpoint of organic matter removal performance, liquid stability, and safety such as flammability. More specifically, the content of the component A1 is preferably 10% by mass or more and 80% by mass or less, more preferably 15% by mass or more and 60% by mass or less, and further preferably 20% by mass or more and 30% by mass or less. When the component A1 is a combination of two or more types, the content of the component A1 is the total content of the two or more types.

The content of the aromatic solvent (component A) in the treatment solution of the present disclosure is preferably 10% by mass or more, more preferably 20% by mass or more, and further preferably 25% by mass or more from the viewpoint of organic matter removal performance and safety such as flammability. Furthermore, the content of the aromatic solvent (component A) is preferably 90% by mass or less, more preferably 70% by mass or less, and further preferably 50% by mass or less from the viewpoint of organic matter removal performance, liquid stability, and safety such as flammability. More specifically, the content of the component Ais preferably 10% by mass or more and 90% by mass or less, more preferably 20% by mass or more and 70% by mass or less, and further preferably 25% by mass or more and 50% by mass or less. When the component Ais a combination of two or more types, the content of the component Ais the total content of the two or more types.

The “content of each component in the treatment solution” of the present disclosure means the amount of each component at the time of use, i.e., at the time a treating-target object starts to be treated with the treatment solution.

In one or more embodiments, the content of each component in the treatment solution of the present disclosure may be regarded as the blending amount of each component in the treatment solution of the present disclosure.

### (Component B: Organic Acid)

The organic acid (also referred to as a “component B” in the following) contained in the treatment solution of the present disclosure may contain, e.g., at least one selected from the group consisting of phenols (component B1) and sulfonic acids (component B2). In one or more embodiments, the component B may contain sulfonic acids. The total content of the phenols (component B1) and the sulfonic acids (component B2) in the component Bis preferably 5% by mass or more, more preferably 10% by mass or more, and further preferably 20% by mass or more. The component B may be one type or a combination of two or more types.

### <Component B1: Phenols>

Examples of the phenols (also referred to as a “component B1” in the following) include phenol and alkylphenols such as p-ethylphenol, p-t-butylphenol, and 2,4,6 trimethylphenol. The component B1 may be one type or a combination of two or more types.

The content of the phenols (component B1) in the treatment solution of the present disclosure is preferably 2% by mass or more, more preferably 5% by mass or more, and further preferably 10% by mass or more from the viewpoint of organic matter removal performance. Furthermore, the content of the phenols (component B1) is preferably 40% by mass or less, more preferably 30% by mass or less, and further preferably 20% by mass or less from the viewpoint of ease of production and liquid stability. More specifically, the content of the component B1 is preferably 2% by mass or more and 40% by mass or less, more preferably 5% by mass or more and 30% by mass or less, and further preferably 10% by mass or more and 20% by mass or less. When the component B1 is a combination of two or more types, the content of the component B1 is the total (content of the two or more types.

### <Component B2: Sulfonic Acids>

Examples of the sulfonic acids (also referred to as a “component B2” in the following) include alkylbenzenesulfonic acids such as m-xylene-4-sulfonic acid (2,4-dimethylbenzenesulfonic acid) and dodecylbenzenesulfonic acid. The component B2 may be one type or a combination of two or more types.

The content of the sulfonic acids (component B2) in the treatment solution of the present disclosure is preferably 10% by mass or more, more preferably 30% by mass or more, and further preferably 50% by mass or more from the viewpoint of ease of production and liquid stability. Furthermore, the content of the sulfonic acids (component B2) is preferably 70% by mass or less, more preferably 65% by mass or less, and further preferably 60% by mass or less from the viewpoint of organic matter removal performance. More specifically, the content of the component B2 is preferably 10% by mass or more and 70% by mass or less, more preferably 30% by mass or more and 65% by mass or less, and further preferably 50% by mass or more and 60% by mass or less. When the component B2 is a combination of two or more types, the content of the component B2 is the total content of the two or more types.

In one or more embodiments, the component Bis preferably the sulfonic acids (component B2) from the viewpoint of improving organic matter removal performance. From the same viewpoint, the component B2 preferably contains an alkylbenzenesulfonic acid, and more preferably contains at least one selected from the group consisting of m-xylene-4-sulfonic acid and dodecylbenzenesulfonic acid.

In one or more embodiments, the component B preferably contains the phenols (component B1) and the sulfonic acids (component B2), more preferably contains alkylphenol and an alkylbenzenesulfonic acid, and further preferably contains p-t-butylphenol and a dodecylbenzenesulfonic acid from the viewpoint of improving organic matter removal performance.

The content of the component Bin the treatment solution of the present disclosure is preferably 5% by mass or more, more preferably 10% by mass or more, and further preferably 20% by mass or more from the viewpoint of organic matter removal performance and liquid stability. Furthermore, the content of the component Bis preferably 85% by mass or less, more preferably 80% by mass or less, and further preferably 75% by mass or less from the viewpoint of organic matter removal performance, liquid stability, and handleability. More specifically, the content of the component Bis preferably 5% by mass or more and 85% by mass or less, more preferably 10% by mass or more and 80% by mass or less, and further preferably 20% by mass or more and 75% by mass or less. When the component Bis a combination of two or more types, the content of the component Bis the total content of the two or more types.

The total content of the component A and the component Bin the treatment solution of the present disclosure is preferably 70% by mass or more, more preferably 80% by mass or more, even more preferably 90% by mass or more, and further preferably 100% by mass from the viewpoint of organic matter removal performance.

The mass ratio A1/B of the component A1 to the component Bin the treatment solution of the present disclosure is preferably 0.2 or more, more preferably 0.25 or more, and further preferably 0.3 or more from the viewpoint of organic matter removal performance and liquid stability. Furthermore, the mass ratio A1/Bis preferably 2.5 or less, more preferably 2.0 or less, and further preferably 1.0 or less from the viewpoint of organic matter removal performance and liquid stability. More specifically, the mass ratio A1/Bis preferably 0.2 or more and 2.5 or less, more preferably 0.25 or more and 2.0 or less, and further preferably 0.3 or more and 1.0 or less.

The mass ratio A/B of the component A to the component Bin the treatment solution of the present disclosure is preferably 0.2 or more, more preferably 0.25 or more, and further preferably 0.3 or more from the viewpoint of organic matter removal performance and liquid stability. Furthermore, the mass ratio A/Bis preferably 2.5 or less, more preferably 1.5 or less, and further preferably 1 or less from the viewpoint of organic matter removal performance and liquid stability. More specifically, the mass ratio A/Bis preferably 0.2 or more and 2.5 or less, more preferably 0.25 or more and 1.5 or less, and further preferably 0.3 or more and 1 or less.

### (Other Components)

The treatment solution of the present disclosure may further contain other components as needed in addition to the component A and the component B. The other components include, e.g., any components that would be used for usual treatment solutions or cleaning compositions. Examples of the other components include solvents other than the component A, acids other than the component B, alkaline agents, surfactants, chelating agents, thickening agents, dispersing agents, rust preventives, polymer compounds, solubilizing agents, antioxidants, preservatives, antifoaming agents, and antibacterial agents.

In one or more embodiments, the treatment solution of the present disclosure preferably contains no water or has a water content of 10% by mass or less. In one or more embodiments, water may be, e.g., ion-exchanged water, RO water, distilled water, pure water, or ultrapure water.

The content of water in the treatment solution of the present disclosure is preferably 10% by mass or less, more preferably 5% by mass or less, and further preferably 0% by mass (i.e., no water is contained).

In one or more embodiments, the treatment solution of the present disclosure may contain substantially no halogen-based compound. For example, the content of the halogen-based compound in the treatment solution of the present disclosure is preferably 1% by mass or less, more preferably 0.1% by mass or less, and further preferably 0% by mass (i.e., no halogen-based compound is contained).

In one or more embodiments, the treatment solution of the present disclosure may contain substantially no alkoxysilane. For example, the content of the alkoxysilane in the treatment solution of the present disclosure is preferably less than 0.5% by mass, more preferably 0.1% by mass or less, and further preferably 0% by mass (i.e., no alkoxysilane is contained).

### (Production Method of Treatment Solution)

In one or more embodiments, the treatment solution of the present disclosure can be produced by blending the component A and the component B, and the optional components (the other components) as needed, with a known method. For example, in one or more embodiments, the treatment solution of the present disclosure may be produced by blending the component A and the component B.

Thus, the present disclosure relates to a method for producing a treatment solution. The production method includes blending at least the component A and the component B. In the present disclosure, the term “blend” includes mixing the component A and the component B, and the optional components (the other components) as needed, simultaneously or in any order. The preferred blending amount of each component in the production method of the treatment solution of the present disclosure may be the same as the preferred content of each component in the treatment solution of the present disclosure, as described above.

### [Treating-Target Object (Object to be Treated)]

In one or more embodiments, the treating-target object (object to be treated) may be a substrate having organic matter. The substrate having organic matter may be, e.g., a substrate having an organic film and/or an organic residue. The organic film may be, e.g., a resin mask or an antireflection film. The organic film may be either a single-layer film or a multilayer film. The organic residue may be, e.g., an etching residue or a resist residue. The substrate may be, e.g., a printed circuit board, a wafer, a copper plate, or an aluminum plate.

In one or more embodiments, the treatment solution of the present disclosure can be suitably used to clean a substrate having a resin mask, a substrate having an antireflection film, or a substrate having a resin mask and an antireflection film.

In the present disclosure, the resin mask serves to protect the surface of a material from treatments such as etching, plating, and heating, and functions as a protective film. In one or more embodiments, the resin mask may be, e.g., a resist layer that has been subjected to both an exposure process and a development process, a resist layer that has been subjected to at least one of an exposure process and a development process (also referred to as an “exposed and/or developed” resist layer in the following), or a cured resist layer.

In one or more embodiments, the resin mask is composed of a resist having physical properties (e.g., solubility in a developing solution) that change with light, an electron beam, etc. Resists are broadly classified into a negative type and a positive type depending on how they react with light or an electron beam. A negative resist has properties such that the solubility in a developing solution decreases when it is exposed to light. In a layer containing the negative resist (also referred to as a “negative resist layer” in the following), the exposed portion is used as a resin mask after the exposure and development processes. A positive resist has properties such that the solubility in a developing solution increases when it is exposed to light. In a layer containing the positive resist (also referred to as a “positive resist layer” in the following), the exposed portion is removed after the exposure and development processes, and the unexposed portion is used as a resin mask. The use of the resin mask with these properties can form fine connections of a circuit board, including, e.g., metal wiring, metal pillars, and solder bumps.

In one or more embodiments, a resin material of the resin mask may be, e.g., a film-like photosensitive resin, a resist film, or a photoresist. Any general-purpose resist film may be used.

Examples of the resin mask include an acrylic acid polymer film, a phenol polymer film, and a cyclized polyisoprene film.

The thickness of the resin mask may be, e.g., 1 μm to 50 μm.

In the present disclosure, the antireflection film has the ability to absorb light and serves to prevent reflection of incident light. In one or more embodiments, the antireflection film is disposed between the resin mask and the substrate.

An inorganic coating material and an organic coating material are known as materials of the antireflection film. Examples of the inorganic coating material include TiN, TiON, TiW, and a spin-on organic polymer. Examples of the organic coating material include high aromatic polymers such as a phenol resin and a phenol resin derivative, and a siloxane compound having alight-absorbing group (e.g., a benzene ring).

Any general-purpose antireflection film may be used, including, e.g., an antireflection film disclosed in JP 2006-343416 A and an antireflection film disclosed in JP 2005-517972 A.

The thickness of the antireflection film may be, e.g., 30 nm to 150 nm.

In one or more embodiments, the treating-target object may be, e.g., a treating-target object to which organic matter is attached. Examples of the treating-target object to which organic matter is attached include an electronic component having a resin mask and an intermediate of the electronic component, and an electronic component having a resin mask and an antireflection film and an intermediate of the electronic component. Examples of the electronic component include at least one component selected from the group consisting of a printed circuit board, a wafer, and metal plates such as a copper plate and an aluminum plate. The intermediate is an intermediate product during the manufacturing process of an electronic component and may include an intermediate product after the resin mask treatment.

The treating-target object to which organic matter is attached may be a substrate that is obtained by, e.g., the steps of forming an insulation film on a substrate; forming an antireflection film on the insulation film; applying a resist to the antireflection film and developing and/or exposing the resist to form a patterned resist film (resin mask); and etching the antireflection film and the insulation film by using the patterned resist film as a mask.

In one or more embodiments, the treating-target object to which organic matter is attached may be a substrate, on the surface of which wiring, connection terminals, etc. are formed by the process of e.g., soldering or plating (e.g., copper plating, aluminum plating, or nickel plating) using the resin mask.

In one or more embodiments, from the viewpoint of a cleaning effect, the treatment solution of the present disclosure can be suitably used to dean the treating-target object to which a resin mask or a plated and/or heated resin mask is attached. The resin mask may be either a negative resin mask or a positive rein mask, and is preferably the negative resin mask because the effects of the present disclosure can easily be provided. The negative resin mask may be, e.g., a negative dry film resist that has been exposed and/or developed. In the present disclosure, the negative resin mask is formed by using a negative resist and may be, e.g., an exposed and/or developed negative resist layer. In the present disclosure, the positive rein mask is formed by using a positive resist and may be, e.g., an exposed and/or developed positive resist layer.

### [Cleaning Method]

In one aspect, the present disclosure relates to a cleaning method that includes cleaning a substrate having organic matter (i.e., a treating-target object) by using the treatment solution of the present disclosure (which is referred to as a “cleaning process” the following). In one or more embodiments, the cleaning process includes bringing the treating-target object into contact with the treatment solution of the present disclosure. The treating-target object may be any of the objects to be treated, as described above. In one or more embodiments, the treatment solution of the present disclosure can be suitably used to dean a substrate having a resin mask, a substrate having an antireflection film, or a substrate having a resin mask and an antireflection film.

In one or more embodiments, the cleaning process includes removing organic matter from a substrate having organic matter. For example, the cleaning process includes peeling a resin mask from a substrate having a resin mask, peeling an antireflection film from a substrate having an antireflection film, or peeling a resin mask and an antireflection film from a substrate having a resin mask and an antireflection film. Each of these processes is referred to as a “peeling process.”

In one or more embodiments, the cleaning method of the present disclosure can efficiently remove the organic matter on the substrate. In one or more embodiments, when the treating-target object is a substrate having a resin mask and an antireflection film, the cleaning method of the present disclosure can efficiently remove both the resin mask and the antireflection film from the substrate.

The treating-target object is cleaned with or brought into contact with the treatment solution of the present disclosure in the following manner. For example, the treating-target object may be immersed in the treatment solution placed in a cleaning bath, or the treatment solution may be sprayed onto the treating-target object (i.e., a shower method). Alternatively, the immersed treating-target object may be irradiated with ultrasonic waves (i.e., an ultrasonic cleaning method). The treatment solution of the present disclosure can be used for cleaning directly without requiring dilution. The treating-target object may be any of the objects to be treated, as described above. The immersion time may be, e.g., 1 minute or more and 10 minutes or less, or 3 minutes or more and 6 minutes or less. The spray time may be, e.g., 1 minute or more and 10 minutes or less, or 3 minutes or more and 6 minutes or less.

In one or more embodiments, the cleaning method of the present disclosure may include rinsing the treating target object with a rinse solution (e.g., water, ethanol, or isopropyl alcohol) after the treating-target object has been in contact with the treatment solution, and drying the rinsed treating-target object. The treating-target object may be rinsed with, e.g., running water and dried by, e.g., air blow drying.

In one or more embodiments, the cleaning method of the present disclosure may include rinsing the treating-target object with water after the treating-target object has been in contact with the treatment solution.

The cleaning method of the present disclosure preferably includes ultrasonic irradiation of the treating-target object in contact with the treatment solution, or spraying of the treatment solution, since these processes can help to enhance the cleaning power of the treatment solution of the present disclosure. In this case, it is more preferable that the ultrasonic waves are at relatively high frequencies. From the same viewpoint, the ultrasonic irradiation is, e.g., preferably 26 to 72 kHz and 80 to 1500 W, and more preferably 36 to 72 kHz and 80 to 1500 W. The spray pressure is preferably relatively high, e.g., 0.1 to 0.3 Pa.

In the cleaning method of the present disclosure, the temperature of the treatment solution is preferably 50° C. or more, and more preferably 90° or more, since this can help to enhance the cleaning power of the treatment solution of the present disclosure. Furthermore, the temperature of the treatment solution is preferably 150° C. or less, and more preferably 130° C. or less from the viewpoint of reducing the effect on the substrate.

### [Removal Method]

In one aspect, the present disclosure relates to a removal method (also referred to as a “removal method of the present disclosure” in the following) that includes removing organic matter present on a substrate having organic matter (i.e., a treating-target object) from the substrate by using the treatment solution of the present disclosure (which is referred to as a “removal process” in the following). In one or more embodiments, the removal process includes peeling a resin mask from a substrate having a resin mask, peeling an antireflection film from a substrate having an antireflection film, or peeling a resin mask and an antireflection film from a substrate having a resin mask and an antireflection film. Each of these processes is referred to as a “peeling process.” The method for removing the organic matter in the removal process may be the same as the cleaning method of the present disclosure described above.

In one or more embodiments, the removal method of the present disclosure can efficiently remove the organic matter on the substrate.

### [Production Method of Electronic Component]

In one aspect, the present disclosure relates to a method for producing an electronic component. The method includes cleaning a treating-target object by using the treatment solution of the present disclosure (which is also referred to as a “cleaning process” in the following). The treating-target object may be any of the objects to be treated, as described above. In one or more embodiments, the cleaning process includes peeling a resin mask from a substrate having a resin mask, peeling an antireflection film from a substrate having an antireflection film, or peeling a resin mask and an antireflection film from a substrate having a resin mask and an antireflection film. Each of these processes is referred to as a “peeling process.” The cleaning method in the cleaning process may be the same as the cleaning method of the present disclosure described above.

The production method of an electronic component of the present disclosure can efficiently remove the organic matter adhering to an electronic component, and thus can produce highly reliable electronic components. Moreover, the use of the cleaning solution of the present disclosure facilitates the removal of the organic matter adhering to an electronic component, thereby reducing the cleaning time and improving the production efficiency of electronic components.

### [Kit]

In one aspect, the present disclosure relates to a kit (also referred to as a “kit of the present disclosure” in the following) used for either the cleaning method of the present disclosure or the production method of an electronic component of the present disclosure. In one or more embodiments, the kit of the present disclosure is used to produce the treatment solution of the present disclosure. The kit of the present disclosure can provide a treatment solution that has a high ability to remove organic matter on a substrate.

In one or more embodiments, the kit of the present disclosure may be, e.g., a kit (two-part treatment solution) that includes a solution (first solution) containing the component A and a solution (second solution) containing the component B so that the two solutions are not mixed with each other. The first solution and the second solution are mixed at the time of use. Each of the first solution and the second solution may contain the above optional components (the other components) as needed.

### EXAMPLES

Hereinafter, the present disclosure will be described in detail by way of examples. However, the present disclosure is not limited to the following examples.

1. Preparation of treatment solution (cleaning composition) in Examples 1 to 7 and Comparative Examples 1 to 7

Treatment solutions (cleaning compositions) in Examples 1 to 7 and Comparative Examples 1 to 7 were each prepared by blending the components in their respective amounts (% by mass, active part) as shown in Tables 1 to 2, and stirring and mixing them together.

The following components were used to prepare the treatment solutions (cleaning compositions) in Examples 1 to 7 and Comparative Examples 1 to 7.

### (Component A1: Aromatic Ether)

Veratrole (1,2-dimethoxybenzene) [manufactured by FUJIFILM Wako Pure Chemical Corporation]
Diphenyl ether [manufactured by FUJIFILM Wako Pure Chemical Corporation]

### (Component A2: Aromatic Hydrocarbon)

Mesitylene [manufactured by FUJIFILM Wako Pure Chemical Corporation]

### (Component A3 Aromatic Alcohol)

Benzyl alcohol[manufactured by FUJIFILM Wako Pure Chemical Corporation]

### (Component B1: Phenols)

Phenol[manufactured by FUJIFILM Wako Pure Chemical Corporation]
p-ethylphenol[manufactured by FUJIFILM Wako Pure Chemical Corporation]
p-t-butylphenol[manufactured by FUJIFILM Wako Pure Chemical Corporation]

### (Component B2: Sulfonic Acids)

m-xylene-4-sulfonic acid[manufactured by FUJIFILM Wako Pure Chemical Corporation]
Dodecylbenzenesulfonic acid[NEOPELEX GS-P manufactured by Kao Corporation]

### (Non-momponent A)

Diisoamyl ether [manufactured by FUJIFILM Wako Pure Chemical Corporation]

2. Evaluation of treatment solution (cleaning composition) in Examples 1 to 7 and Comparative Examples 1 to 7

The treatment solutions (cleaning compositions) in Examples 1 to 7 and Comparative Examples 1 to 7 were evaluated as follows.

### [Test Piece]

A test piece was a 20 mm×20 mm substrate (Si wafer) having a thin film. The following two types of organic coating materials were used as the thin film.

A thin film A was a siloxane compound-containing film with a thickness of 45 nm.

A thin film B was a phenol resin derivative fin with a thickness of 90 nm.

### [Evaluation of Cleaning Performance (Thin Film Removal Performance)]

First, 50 mL of the treatment solution (cleaning composition) in each of Examples 1 to 7 and Comparative Examples 1 to 7 was placed in a 100 mL beaker and heated to 120° C. Then, the test pieces having the thin films A, B were immersed in the treatment solution for 5 minutes.

Two 100 mL beakers, each containing 50 mL of isopropyl alcohol at room temperature, were prepared separately. The test pieces were taken out of the treatment solution (cleaning composition) and rinsed by immersing them successively in the isopropyl alcohol in each beaker. The test pieces were then allowed to stand and dried at room temperature.

Next, image data was obtained by photographing the amount of the thin film remaining on each of the test pieces with a digital camera. The image data was digitized using image processing software (ImageJ) to determine the area of the remaining thin film, and the cleaning performance (thin film removal performance) was evaluated. Tables 1 to 2 show the results.

$$Cleaning rate = ( area of portion of test piece from which thin film has been removed after cleaning ) / ( area of test piece ) \times 100$$

### <Evaluation Criteria>

A: cleaning rate of 90% or more
B: cleaning rate of 70% or more and less than 90%
C: cleaning rate of 50% or more and less than 70%
D: cleaning rate of less than 50%

TABLE 1

| | | | | Comparative Example | | | | Example | | |
|---|---|---|---|---|---|---|---|---|---|---|
| | | | | 1 | 2 | 3 | 4 | 1 | 2 | 3 |
| Component | A1 | Aromatic ether | veratrole | | | | | 14 | | |
| A | | | diphenyl ether | | | | | | 69 | 69 |
| | A2 | Aromatic hydrocarbon | mesitylene | | 70 | 70 | 56 | 42 | | |
| | A3 | Aromatic alcohol | benzyl alcohol | 70 | | | | | | |
| Component | B1 | Phenols | phenol | 30 | 30 | | | | | |
| B | | | p-ethylphenol | | | 30 | 23 | 23 | 28 | |
| | | | p-t-butylphenol | | | | | | | 28 |
| | B2 | Sulfonic acids | m-xylene-4-sulfonic acid | | | | 21 | 21 | 3 | 3 |
| | | | dodecylbenzenesulfonic acid | | | | | | | |

| Non-component A | Aliphatic ether | diisoamyl ether | | | | | | | |
|---|---|---|---|---|---|---|---|---|---|
| Total (% by mass) | | | 100 | 100 | 100 | 100 | 100 | 100 | 100 |
| Cleaning | Thin film A removal performance | | B | A | A | A | A | A | A |
| performance | | | 85% | >99% | >99% | >99% | >99% | >99% | >99% |

| | | | | | | | |
|---|---|---|---|---|---|---|---|
| Thin film B removal performance | D | D | D | B | A | A | A |

| | | | | | | |
|---|---|---|---|---|---|---|
| ≐0% | ≐0% | ≐0% | 85% | >99% | >99% | >99% |

| | | | | Example | | Comparative Example | | |
|---|---|---|---|---|---|---|---|---|
| | | | | 4 | 5 | 5 | 6 | 7 |
| Component | A1 | Aromatic ether | veratrole | | | | | |
| A | | | diphenyl ether | 64 | 29 | 100 | | |
| | A2 | Aromatic hydrocarbon | mesitylene | | | | | |
| | A3 | Aromatic alcohol | benzyl alcohol | | | | | |
| Component | B1 | Phenols | phenol | | | | 100 | |
| B | | | p-ethylphenol | | | | | |
| | | | p-t-butylphenol | 26 | 15 | | | |
| | B2 | Sulfonic acids | m-xylene-4-sulfonic acid | | | | | 30 |
| | | | dodecylbenzenesulfonic acid | 10 | 56 | | | |

| Non-component A | Aliphatic ether | diisoamyl ether | | | | | 70 |
|---|---|---|---|---|---|---|---|
| Total (% by mass) | | | 100 | 100 | 100 | 100 | 100 |
| Cleaning | Thin film A removal performance | | A | A | D | D | D |
| performance | | | >99% | >99% | ≐0% | ≐0% | ≐0% |

| | | | | | |
|---|---|---|---|---|---|
| Thin film B removal performance | A | A | D | D | D |

| | | | | |
|---|---|---|---|---|
| >99% | >99% | ≐0% | ≐0% | ≐0% |

TABLE 2

| | | | | | | | Comparative |
|---|---|---|---|---|---|---|---|
| | | | | Example | | | Example |
| | | | | 4 | 6 | 7 | 7 |
| Component A | A1 | Aromatic ether | diphenyl ether | 64 | 64 | 70 | |
| Component B | B1 | Phenols | p-t-butylphenol | 26 | | | |
| | B2 | Sulfonic acids | m-xylene-4-sulfonic acid | | | 30 | 30 |
| | | | dodecylbenzenesulfonic acid | 10 | 36 | | |

| Non-component A | Aliphatic ether | diisoamyl ether | | | | 70 |
|---|---|---|---|---|---|---|
| Total (% by mass) | | | 100 | 100 | 100 | 100 |
| Cleaning | Thin film A removal performance | | A | A | A | D |
| performance | | | >99% | >99% | >99% | ≐0% |

| | | | | |
|---|---|---|---|---|
| Thin film B removal performance | A | A | A | D |

| | | | |
|---|---|---|---|
| >99% | >99% | >99% | ≐0% |

As shown in Table 1, the treatment solutions (cleaning compositions) in Examples 1 to 5, each of which contained the aromatic solvent (component A) containing the aromatic ether (component A1) and the organic acid (component B), are found superior in removal performance for the thin film A to the treatment solution (cleaning composition) in Comparative Example 5, which did not contain the organic acid (component B), the treatment solution (cleaning composition) in Comparative Example 6, which did not contain the aromatic solvent (component A) containing the aromatic ether (component A1), and the treatment solution (cleaning composition) in Comparative Example 7, which contained the non-component A as an aromatic solvent. Moreover, the treatment solutions (cleaning compositions) in Examples 1 to 5, each of which contained the aromatic solvent (component A) containing the aromatic ether (component A1), are also found superior in removal performance for the thin film B to the treatment solutions (cleaning compositions) in Comparative Examples 1 to 4, each of which contained the aromatic solvent (component A) without the aromatic ether (component A).

As shown in Table 2, the treatment solutions (cleaning compositions) in Examples 4,6, and 7, each of which contained the aromatic solvent (component A) containing diphenyl ether (component A1) and the sulfonic acids (component B2), are found superior in removal performance for both the thin film A and the thin film B.

### INDUSTRIAL APPLICABILITY

The present disclosure provides a treatment solution that has ahigh ability to remove organic matter on a substrate. The use of the treatment solution of the present disclosure can improve the performance and reliability of electronic components produced, resulting in high productivity of semiconductor devices.

1-9. (canceled)

10. A removal method comprising:
removing organic matter present on a substrate from the substrate by using a treatment solution,
wherein the treatment solution comprises an aromatic solvent (component A) and an organic acid (component B),
the component A contains aromatic ether (component A1), and
the component A1 contains diphenyl ether.

11. The removal method according to claim 10, wherein the treatment solution contains no halogen-based compound.

12. The removal method according to claim 10, wherein the component B contains phenols (component B1).

13. The removal method according to claim 10, wherein the component B contains sulfonic acids (component B2).

14. The removal method according to claim 10, wherein the component B contains phenols (component B1) and sulfonic acids (component B2).

15. The removal method according to claim 14, wherein the component B contains alkylphenol and an alkylbenzenesulfonic acid.

16. The removal method according to claim 14, wherein the component B contains p-t-butylphenol and a dodecylbenzenesulfonic acid.

17. The removal method according to claim 12, wherein a content of the phenols (component B1) in the treatment solution is 2% by mass or more and 40% by mass or less.

18. The removal method according to claim 13, wherein a content of the sulfonic acids (component B2) in the treatment solution is 10% by mass or more and 70% by mass or less.

19. The removal method according to claim 10, wherein a total content of the component A and the component B in the treatment solution is 70% by mass or more.

20. The removal method according to claim 10, wherein a mass ratio Alt of the component A to the component B in the treatment solution is 0.2 or more and 2.5 or less.

21. The removal method according to claim 10, wherein a mass ratio A1/B of the component A1 to the component B in the treatment solution is 0.2 or more and 2.5 or less.

22. A treatment solution for a semiconductor substrate, comprising:
an aromatic solvent (component A) and an organic acid (component B),
wherein the component A contains aromatic ether (component A1), and
the component A1 contains diphenyl ether.

23. A method for producing an electronic component, comprising:
a cleaning process of cleaning a treating-target object by using a treatment solution,
wherein the treatment solution comprises an aromatic solvent (component A) and an organic acid (component B),
the component A contains aromatic ether (component A1), and
the component A1 contains diphenyl ether.
